(19) United States
(12) Patent Application Publication
(10) Pub. No.: US 2006/0080583 A1
(43) Pub. Date: Apr. 13, 2006

(54) Store scan data in trace arrays for on-board software access

(75) Inventors: John Samuel Liberty, Round Rock, TX (US); Mack Wayne Riley, Austin, TX (US); John Fred Spannaus, Austin, TX (US)

Correspondence Address: IBM CORPORATION (CS);C/O CARR LLP, 670 FOUNDERS SQUARE, 900 JACKSON STREET, DALLAS, TX, 75202, US

(73) Assignee: International Business Machines Corporation, Armonk, NY (US)

(21) Appl. No.: 10/960,612

(22) Filed: Oct. 7, 2004

(51) Int. Cl. G01R 31/28

(52) U.S. Cl. 714/726

(57) ABSTRACT

In the present invention, register values are obtained by scanning, and are then written to one or more trace arrays on the chip. The scan data in the trace arrays is then read out by software. The register scan data can be recirculated among the registers, and addition scans can then be performed and written to the one or more trace arrays.

### TECHNICAL FIELD

The present invention relates generally to the testing of chips and, more particularly, to the on-board software access of register scan data.

### BACKGROUND

To test a chip, it may be necessary to examine the internal workings of the hardware, which are not directly accessible by software. For example, the hardware may hang on a branch instruction, or a multiplier may occasionally produce a 1 instead of a 0 in a bit. To examine the internal state of the chip when these errors occur, it is necessary to examine registers, which store intermediate values used in the execution of instructions. These register values are not accessible to software. Extensive use is made of the registers. For example, there may be six intermediate values in a call to a multiplier.

External monitoring can be used to gain access to the values of these registers. The values of the registers are passed to pins on the chip, and the pins are connected to the external device. The scan test architecture is a built-in method for passing the values of these registers to the pins. In this architecture, the registers are connected in a scan chain or ring, separately from their normal functional connection. Input data can be serially shifted into the registers, and output data serially shifted out of them to the pins. To examine the contents of the registers at a particular point in their operation, they are switched to scan mode, and the values in the registers are moved out using the scan protocol.

This method of gaining access to the register values has limited utility. First, the use of these devices can be expensive. Further, considerable testing time may be required. External monitoring requires that the external device be connected to the chip while the chip is running. If an error occurs only rarely, the external device must be connected until the bug occurs. It cannot be connected to the chip after the error has occurred.

Therefore, there is a need for a method and system of testing chips that can access the values stored in the internal registers without the need for costly external devices.

### SUMMARY OF THE INVENTION

In the present invention, register values are obtained by scanning, and are then written to one or more trace arrays on the chip. The scan data in the one or more trace arrays can be read out by software.

### BRIEF DESCRIPTION OF THE DRAWINGS

For a more complete understanding of the present invention and the advantages thereof, reference is now made to the following descriptions taken in conjunction with the accompanying drawing, in which:

FIG. 1 shows a block diagram of a register;

FIG. 2 shows a block diagram of a system for scanning registers and storing the values on-chip; and

FIG. 3 shows a flow diagram illustrating the scanning of registers and the storing of the values on-chip.

### DETAILED DESCRIPTION

In the following discussion, numerous specific details are set forth to provide a thorough understanding of the present invention. However, it will be apparent to those skilled in the art that the present invention may be practiced without such specific details. In other instances, well-known elements have been illustrated in schematic or block diagram form in order not to obscure the present invention in unnecessary detail.

It is further noted that, unless indicated otherwise, all functions described herein may be performed in either hardware or software, or some combination thereof. In a preferred embodiment, however, the functions are performed by a processor such as a computer or an electronic data processor in accordance with code such as computer program code, software, and/or integrated circuits that are coded to perform such functions, unless indicated otherwise.

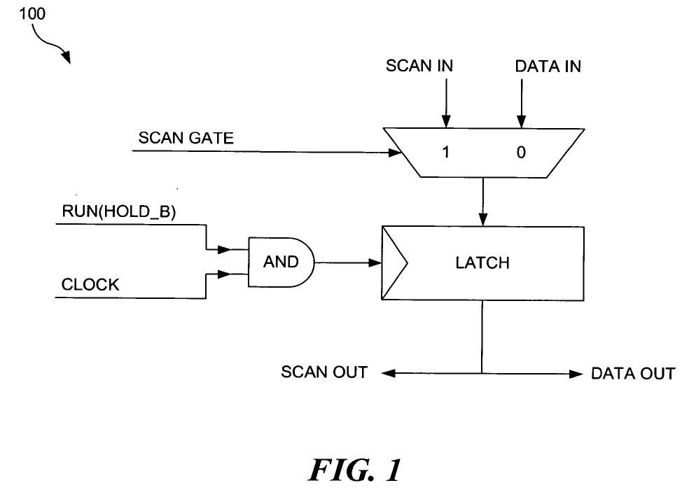

FIG. 1 shows a block diagram of a register 100. Three inputs, ScanGate, Run(Hold_b), and Clock determine the operation of the register. When the clock is off or Run(Hold_b) is 0, the register is inactive. In both cases, the register retains its current value. When the clock is on and Run(Hold_b) is 1, the ScanGate input determines the function of the register. The register operates in scan mode with a ScanGate input of 1, inputting and outputting scan data. With a ScanGate input of 0, the register operates in functional mode, inputting and outputting data.

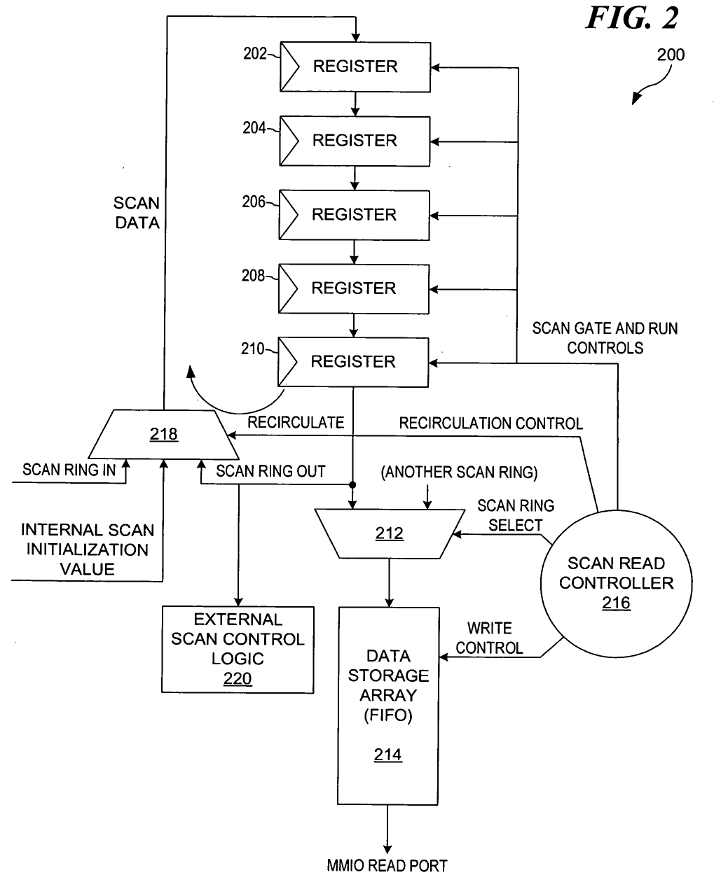

FIG. 2 shows a block diagram of a system 200 for scanning registers and storing the values on-chip. The diagram depicts registers 202 through 210, which form a scan chain or ring. The scan output from each of registers 202 through 208, respectively, is sent to the scan input for each of registers 204 through 210, respectively. The scan output from scan register 210 can be sent to the scan input for register 202 through a multiplexer 218. In addition, scan output from register 210 can be sent indirectly to the data storage array 214, or to external storage. Thus, through the scan protocol, all of the registers 202 through 210 can send their values to the data storage array 214 or to the external scan control logic 220. For example, register 202 can send its output in steps through registers 204, 206, 208, and 210, and finally to the data storage array 214 or to the external scan control logic 220. Thus, the process of scanning can gain access to the values stored in all of the registers in a scan chain. The registers in other scan rings are not depicted in FIG. 2.

The scan read controller 216 controls whether and how to scan. Scan read controller 216 selects between a functional mode and a scan mode for the registers 202 through 210, and the registers in other scan rings, by sending input to the scan gates of the registers 202 through 210, and to the registers in the other scan chains. Scan read controller 216 selects between active and inactive modes by sending input to the Run(Hold-b) inputs of the registers 202 through 210 and registers in other scan rings. It also controls the selection of a scan ring or rings to be scanned. A chip can contain a million registers, comprised of a thousand different scan chains. To perform a scan of the selected ring or rings, the scan read controller 216 would send an input of 1 to the scan gates of the registers in those rings, putting them in scan mode. The scan read controller would render the registers in the non-selected rings inactive by sending a 0 to the Run(Hold-b) inputs of those registers.

The scan read controller 216 also controls whether to recirculate the values of the registers 202 through 210 in the scan chain. Recirculation can restore the values of the registers before the scan. The system can thereby resume its operation at the state before the scan. Thus, the system 200 can take successive snapshots of register values by performing scans and recirculating the values among the registers in the chains that were scanned. In addition, the system 200 can gather register values in excess of the capacity of the data storage array 214. It repeats the process of performing a scan of registers, writing the register values to the data storage array 214, and recirculating the values. Each time, the system 200 scans a set of registers not scanned before. During these successive scans, the registers retain their values and are not switched into functional mode. The values in the data storage array 214 are read out before the desired register values are overwritten.

The scan read controller 216 also controls the disposition of the output from the scan ring. The scan ring output can be written to the data storage array 214, under the control of the scan read controller 216. The scan ring controller 216 directs a multiplexer 212 to pass through the values from this scan chain to the data storage array 214. The data in the data storage array 214 can then be accessed by software. Similarly, to store values from another scan ring, the scan ring controller 216 directs the multiplex 212 to pass through the values from the other scan chain to the data storage array 214. Additionally, the scan ring output can be directed to the external scan control logic 220, and read by an external device.

The scan read controller 216 provides an interface to software programs attempting to access scan chain values. The software programs can send one or more scan requests to the scan read controller 216. The scan ring input allows the registers 202 through 210 to be initialized. For example, if a certain operation produces an error, the registers 202 through 210 can be initialized with the initial state for the operation. The multiplexer 218, under the control of the scan read controller 216, can load into a register or registers of the scan chain, a value from the scan ring in port or a value from another register, which is a third input to the multiplexer 218. The operation can then be performed, and the register values scanned.

This system 200 for scanning registers and storing the values on-chip allows accessing the values stored in the internal registers without the need for costly external devices. The values of the registers are scanned and stored in the data storage array 214. The values can then be accessed by software.

Other embodiments of the invention can have additional elements. A counter or counters can be added to the system 200 to allow the counting of the number of successive scans of a particular scan chain or scan chains. The scanning can be stopped after a particular count of scans. The counter can also allow the sampling of successive scans. For example, the registers in a scan chain can be scanned every 100^{th} cycle of functional operation.

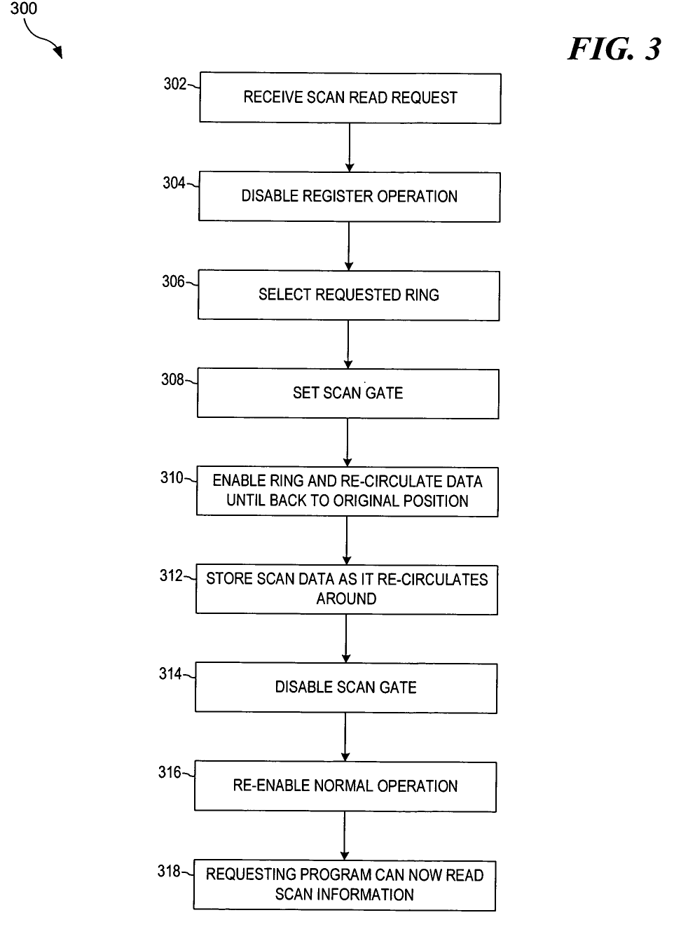

FIG. 3 shows a flow diagram illustrating the scanning of registers and the storing of the values on-chip. In step 302, the scan read controller 216 receives a request to read scan data. In step 304, the register operation of the registers, both those in the scan chain being scanned and in other registers, is disabled, by sending a 0 to the RUN(Hold_b) input. Otherwise, the normal operations of the registers not involved in the register scan chain being scanned might interfere with the operations of the scan. Alternatively, the normal operations in the registers not scanned might produce erroneous results, because of interactions with the scan chain being scanned. In step 306, the scan read controller 216 selects the requested ring or rings for scanning. In step 308, the scan gate is set. The ScanGate input of the registers is set to put the registers into scan mode. In step 310, the scan ring is enabled. The registers in the scan chain or scan chains being scanned are set to operate in scan mode. Then, the values are shifted from register to register, going from the scan-out of one to the scan-in of another until the data is back to its original positions. In this way, the system can resume functional operation in the same state that it was in when it was switched to scan mode. In step 312, the scan data is stored in a trace array or other memory element as it is recirculating. In this way, the scan data can be accessible to software. The data can be accessed in a variety of ways. In the simplest way, the data is read out after each scan cycle. Alternatively, the results of several scans can be accumulated before data is read out. For example, scans can be repeated until a particular condition occurs. Alternatively, scans can be repeated until the memory element is full.

In step 314, the scan gate is disabled. The ScanGate input of the registers is set to return the registers to functional mode. In step 316, normal operation is re-enabled. In step 318, as a result of the scan of the data in the registers in the scan chain, and the storing of the data into a trace array or other memory element, the data is accessible to software. The software program that requested the scan can now read the scan information. As a result of the execution of this method, the scan data is accessible without resort to an expensive external device.

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Many such variations and modifications may be considered desirable by those skilled in the art based upon a review of the foregoing description of preferred embodiments. Accordingly, it is appropriate that the appended claims be construed broadly and in a manner consistent with the scope of the invention.

1. A system for the software access of register scan data, comprising:
one or more scan chains of registers; and
one or more trace arrays, configured to be accessible to software programs;
wherein the system is configured for the register scan data of at least one of the one or more scan chains of registers to be written to the one or more trace arrays.

2. The system of claim 1, further comprising a scan read controller, configured to control the scanning of the one or more scan chains of registers and the writing of the register scan data to the one or more trace arrays.

3. The system of claim 1, further comprising an external control logic, configured to control the writing of the register scan data to an external device.

4. The system of claim 1, further comprising an interval counter, configured so that the register scan data is written to the trace array when the interval counter reaches a specified count.

5. The system of claim 1, further comprising a counter, wherein the system is configured so that the writing of register scan data to the one or more trace arrays is halted when the counter reaches a specified value.

6. A method for accessing the values of registers on a computer chip with software, the method comprising the steps of:
scanning one or more scan chains of registers;
writing the register scan data to one or more on-chip trace arrays; and
accessing the register scan data through software.

7. The method of claim 6, further comprising the step of recirculating the register scan data to the one or more scan chains of registers.

8. The method of claim 7, further comprising the step of switching the one or more scan chains of registers to functional mode.

9. The method of claim 8, further comprising the steps of:
performing an addition scan of one or more scans of registers, after the switching of one or more scan chains of registers to functional mode; and
writing the additional register scan data to the one or more on-chip trace arrays.

10. The method of claim 7, further comprising the steps of:
scanning an additional set of one or more scan chains of registers disjoint from the first set of one or more scan chains of registers; and
writing the register scan data from the scan of the additional set of one or more scan chains to the one or more on-chip trace arrays;
wherein the recirculating after the scan of the first set of one or more scan chains restores all of the registers to their state immediately before the first scan.

11. The method of claim 7, wherein the writing of register scan data to the one or more trace arrays is halted when the counter reaches a specified value.

12. The method of claim 7, wherein the writing to the one or more trace arrays is continued until the trace array is full.

13. The method of claim 6, wherein the register scan data is written to the one or more scan chains of registers when an interval counter reaches a specified count.

14. A method for initializing the values of one or more registers in a scan ring on-chip, the method comprising the steps of:
inputting the values into the scan ring; and
serially shifting the values through the scan ring until the values are stored in the one or more registers.

15. A computer program product for accessing the values of registers on a computer chip with software, the computer program product having a medium with a computer program embodied thereon, the computer program comprising:
computer code for scanning one or more scan chains of registers;
computer code for writing the register scan data to one or more on-chip trace arrays; and
computer code for accessing the register scan data through software.

16. The computer program product of claim 15, further comprising computer code for recirculating the register scan data to the one or more scan chains of registers.

17. The computer program product of claim 16, further comprising computer code for switching the one or more scan chains of registers to functional mode.

18. The computer program product of claim 17, further comprising:
computer code for performing an addition scan of one or more scans of registers, after the switching of one or more scan chains of registers to functional mode; and
computer code for writing the additional register scan data to the one or more on-chip trace arrays.

19. The computer program product of claim 16, further comprising:
computer code for scanning an additional set of one or more scan chains of registers disjoint from the first set of one or more scan chains of registers; and
computer code for writing the register scan data from the scan of the additional set of one or more scan chains to the one or more on-chip trace arrays;
wherein the recirculating after the scan of the first set of one or more scan chains restores all of the registers to their state immediately before the first scan.

20. The computer program product of claim 16, wherein the writing of register scan data to the one or more trace arrays is halted when the counter reaches a specified value.

21. The computer program product of claim 16, wherein the writing to the one or more trace arrays is continued until the trace array is full.

22. The computer program product of claim 15, wherein the register scan data is written to the one or more scan chains of registers when an interval counter reaches a specified count.

23. A computer program product for initializing the values of one or more registers in a scan ring on-chip, the computer program product having a medium with a computer program embodied thereon, the computer program comprising:
computer code for inputting the values into the scan ring; and
computer code for serially shifting the values through the scan ring;
wherein the values are serially shifted through the scan ring until the values are stored in the one or more registers.
